(19) United States
(12) Patent Application Publication
(10) Pub. No.: US 2006/0022295 A1
(43) Pub. Date: Feb. 2, 2006

(54) Evaluation method and manufacturing method of semiconductor device

(76) Inventors: Atsuko Takafuji, Kokubunji (JP); Mari Nozoe, Hino (JP); Kiyonori Oyu, Ome (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/186,831

(22) Filed: Jul. 22, 2005

(30) Foreign Application Priority Data
Jul. 23, 2004 (JP) JP2004-215183

(51) Int. Cl. H01L 23/58; H01L 29/00; G01R 31/305

(52) U.S. Cl. 257/495; 257/509; 324/751

(57) ABSTRACT

The electron beam is irradiated several times at predetermined intervals to the wafer surface on which the plugs are exposed in the course of the manufacturing process so that the pn junction is in the reverse bias state. Then, the irradiation conditions of the electron beam are changed while monitoring the charging voltage on the plug surface, and the secondary electron signals of the circuit pattern are obtained under the irradiation conditions that the charging is within a desired range, thereby evaluating the leakage property. Since the charging voltage of the pn junction is relaxed depending on the magnitude of the leakage current during the interval, the leakage property is evaluated based on the luminance signals of the voltage contrast image. By measuring the charging voltage and setting it within a desired range, the evaluation result reflects the state in the actual operation. Therefore, the accuracy is enhanced.

### CROSS-REFERENCE TO RELATED APPLICATION

The present application claims priority from Japanese Patent Application No. JP2004-215183 filed on Jul. 23, 2004, the content of which is hereby incorporated by reference into this application.

### TECHNICAL FIELD OF THE INVENTION

The present invention relates to a technology for evaluating electrical properties of a semiconductor device having a pn junction portion. More particularly, the present invention relates to a technology for the nondestructive and noncontact evaluation of electrical properties of a pn junction portion formed on a semiconductor wafer in the course of the manufacturing process of a semiconductor device.

### BACKGROUND OF THE INVENTION

The conventional semiconductor device has a pn junction formed therein. In general, the pn junction is formed under the condition capable of reducing junction leakage. However, the pn junction with high leakage is formed only occasionally due to the failure in the manufacturing process. For example, when the pn junction with high leakage is formed in a memory product, the data written therein is lost. The pn junction with high leakage as described above is called a leakage failure, a refresh failure, or a retention failure.

As an evaluation method of the junction leakage failure, the method in which the electrical properties are directly evaluated with probes by the electric test for a completed product is known (Hereinafter, this method is called simply an electric test.). In this method, however, even if the leakage failure occurs in the initial stage of the manufacturing process, that is, in the ion implantation step or the thermal treatment step, the occurrence of the leakage failure cannot be detected until the product is completed and the electric test is executed.

Meanwhile, an evaluation method of the electrical properties of a wafer by using electron beam in the course of the manufacturing process is also known. For example, Japanese Patent Laid-Open Publication No. 6-326165 describes the method of evaluating the occurrence of the leakage failure by measuring the substrate absorption current. However, since the substrate current is weak, it is necessary to accumulate the signals by decreasing the scanning speed of the electron beam, and the method is not suitable for the high-speed evaluation in a wide area. Also, the method of detecting the junction leakage failure is not described.

Also, Japanese Patent Laid-Open Publication No. 4-151846, No. 11-121561 and No. 11-8278 describe the method of inspecting electrical failure of a semiconductor circuit by using a voltage contrast image. The voltage contrast image is obtained by the imaging of detected secondary electrons generated from a wafer charged by irradiating electron beam, and is an image reflecting the charging state of a pattern. Japanese Patent Laid-Open Publication No. 4-151846 and No. 11-121561 disclose the technology for detecting the open/short failure in the connection state of the pn junction based on the voltage contrast image. Also, Japanese Patent Laid-Open Publication No. 2000-208579 discloses that the electrical connection of contact holes formed on the p diffusion layer and the n diffusion layer can be obtained from the voltage contrast image. However, these conventional technologies do not describe the method of detecting the leakage failure in the junction portion.

On the other hand, as the technology for quickly measuring the leakage property of the junction portion in a wide area, Japanese Patent Laid-Open Publication No. 2002-9121 and No. 2003-1294280 are known. In these methods, the electron beam is irradiated several times to the surface of a wafer to form the reverse bias state in the pn junction portion, the difference in charging state caused by the difference of the leakage current is made obvious, and then, the voltage contrast image is obtained to evaluate the variation in leakage property.

### SUMMARY OF THE INVENTION

As described in the conventional technologies, the method of electrically inspecting a chip completed through the wafer process (electric test) has been commonly used for the evaluation of the leakage failure occurring in the semiconductor device, in particular, the junction leakage. However, the process of ion implantation and thermal treatment for forming the junction is performed in the early stage of the manufacturing process. Therefore, even if the failure occurs in this stage, the failure cannot be detected until the wafer is completed and the electric test is executed, and it takes a considerable amount of time from the occurrence of the failure to the implementation of the measures for the failure. Also, in the development stage of the semiconductor, the failure in the formation of the minute patterns frequently occurs in each process. When such a failure occurs, the leakage failure cannot be detected even by-the electric test. More specifically, in the conventional case, only after the development of the forming process of a minute pattern is finished and it becomes possible to prevent the occurrence of the failure in this process, the failure in the early stage of the manufacturing process is detected in the evaluation using the completed wafer. Therefore, a great amount of time, for example, about several months is required for its solution, which becomes a factor to extend the development period of the semiconductor.

Also, in the inspecting method in which the electron beam is irradiated to transistors to measure the leakage amount based on the absorption current, since the absorption current is weak, it takes a significant time to inspect one area. Therefore, it is not suitable for evaluating the leakage property of a wide area of the wafer in a practical time.

Also, even in the method in which the electron beam is irradiated to the wafer which is being processed and the electrical properties of the semiconductor device are inspected based on the voltage contrast, the failure of the junction leakage cannot be inspected.

Furthermore, in the evaluation method of the leakage property in which the electron beam is intermittently irradiated several times to the wafer to apply the reverse bias voltage to the pn junction so that the variation in leakage property at the junction portion is made obvious and the secondary electron image reflecting the leakage property is obtained, the charging state which occurs at the pn junction portion when irradiating the electron beam is unknown. Therefore, when the applied voltage becomes higher in comparison with the actual operation condition of the semiconductor product, the leakage property evaluation does not reflect the state of the actual operation. Also, in order to execute the evaluation in the course of the process, which is equivalent to the electric test performed after the completion of the device, it is necessary to accurately translate the evaluation result by the electron beam into the absolute value of the leakage current at the junction. However, the technology for securing the accuracy in this translation method into the leakage current is not disclosed in the conventional technologies. In addition, the technology for mutually comparing the value results while maintaining the quantitativity thereof in the case where various samples are measured by a plurality of different machines is not also disclosed.

Consequently, in the conventional technology, the variation and fluctuation in junction leakage property obtained by the electric test cannot be accurately measured at a practical speed in the course of the manufacturing process on the semiconductor manufacturing line.

An object of the present invention is to provide a method for evaluating leakage property of a semiconductor device capable of solving the problems described above. In this method, the leakage property of a pn junction which forms a semiconductor device on a wafer can be accurately measured at a practical speed in a noncontact manner in the early stage of the semiconductor manufacturing process, the magnitude of leakage current and its distribution and the relation between the leakage current and the leakage occurrence position are clarified to grasp the problems in the course of the process, and thus, measures for the problems can be quickly taken for the manufacturing process. In addition, another object of the present invention is to provide the method for quickly inspecting a wafer in the course of the process in a noncontact manner so as to grasp the distribution of the leakage failure and the leakage current and estimate the yield of the samples and manufacturing process in an early stage of the manufacture.

Further, another object of the present invention is to provide a method and system for evaluating the leakage property and a manufacturing method of a semiconductor device, in which the technologies described above are applied to the semiconductor device and other minute patterns formed through various types of processes so as to perform the optimization of the process for forming the junction and the management of the process, and the results thereof are reflected on the manufacturing conditions to improve the reliability of the semiconductor device and contribute to the reduction of the percent defective.

The above and other objects and novel characteristics of the present invention will be apparent from the description of this specification and the accompanying drawings.

The typical ones of the inventions disclosed in this application will be briefly described as follows.

More specifically, for the achievement of the above-described objects, in the present invention, the applied voltage almost equal to the reverse bias voltage applied to the pn junction in a semiconductor device in an actual operation or the applied voltage in the range where the leakage property has the linearity to that in the actual operation to be predicable, that is, the voltage in the range where the acceleration test can be performed is set, and the charging voltage on the surface of the plug of the wafer is measured to monitor whether or not the voltage is in the set range. Then, based on the results thereof, the feedback is given to change irradiation conditions of the charged particle beam so that the voltage is set within the desired range, and when it is confirmed that the voltage can be set within the desired range, the junction leakage property of the wafer is evaluated, and then, the result thereof is obtained. In the property evaluation, by focusing attention on the fact that the signal intensity of the voltage contrast signal obtained from the wafer after forming the pn junction is changed depending on the reverse bias current of the pn junction, the reverse bias current is determined based on the voltage contrast signal. More specifically, the charged particle beam is irradiated several times at predetermined intervals to the surface of the wafer on which the pn junction is formed in the course of the process under the condition that the junction is in a reverse bias state, and the generated secondary electron signals are detected and imaged to monitor it. By doing so, the relaxation time property of the reverse bias charging voltage of the pn junction is evaluated. As a result, since the charging voltage of the pn junction is relaxed depending on the magnitude of the reverse bias current in the beam irradiation interval, the reverse bias current can be determined based on the luminance signal correlating to the secondary electron signal amount from the image information, that is, the voltage contrast signal. Also, for the calibration of the evaluation data, the secondary electron images of a sample having complete electrical conduction to the holder on which the wafer is mounted and a sample having no electrical conduction thereto are obtained under the same electron beam irradiation conditions as those of the evaluation, and the images are retained as the reference data.

Also, in the present invention, the manufacturing conditions in the device manufacturing process are changed as parameters and the optimization of the process conditions can be performed in the course of the process.

The effect obtained by the representative one of the inventions disclosed in this application will be briefly described as follows.

That is, according to the representative effect obtained by the means described above, the electrical properties of the pn junction portion formed on a wafer can be evaluated in the course of the manufacturing process of a semiconductor device having the pn junction under the same condition as that of the actual operation.

### BRIEF DESCRIPTIONS OF THE DRAWINGS

FIG. 1 is a diagram showing the flow of the evaluation method of leakage property of a semiconductor device according to the present invention;

FIG. 2 is a diagram showing the structure of the system for evaluating the property of a semiconductor device according to the present invention;

FIG. 3 is a conceptual diagram in which the electron beam irradiation system is enlarged;

FIG. 4 is a diagram showing the arrangement of the electrodes from the wafer to the secondary electron detection system;

FIG. 5 is a graph showing the data retention property of the DRAM with the probability distribution;

FIG. 6 is a diagram showing the target to be inspected;

FIG. 7 is a graph showing the change in voltage in the inspection process;

FIG. 8 is a graph showing the change in the amount of secondary electron signals in the inspection process;

FIG. 9 is a graph showing the relation between the voltage contrast signal and the leakage current;

FIG. 10 is a graph showing the relation between the voltage applied to the junction and the leakage current;

FIG. 11 is a graph showing the relation between the voltage applied to the junction and the charging voltage on the plug surface;

FIG. 12 is a graph showing the energy distribution of secondary electrons;

FIG. 13A and 13B are explanatory diagrams for the measurement of the charging voltage;

FIG. 14 is a graph showing the relation between the signal amount and the filter voltage at the time of the measurement of the charging voltage;

FIG. 15A to FIG. 15D are diagrams showing the flow of the measurement of the charging voltage from the voltage contrast image and the evaluation of the leakage property;

FIG. 16 is a graph for comparing the data retention time in the three types of samples fabricated under the different manufacturing process conditions;

FIG. 17 is a diagram (1) showing the manufacturing process of the stack-type DRAM;

FIG. 18 is a diagram (2) showing the manufacturing process of the stack-type DRAM;

FIG. 19 is a diagram (3) showing the manufacturing process of the stack-type DRAM; and

FIG. 20 is a diagram (4) showing the manufacturing process of the stack-type DRAM.

### DESCRIPTIONS OF THE PREFERRED EMBODIMENTS

Hereinafter, embodiments of the present invention will be described in detail with reference to the accompanying drawings.

### First Embodiment

In this embodiment, the evaluation method of leakage property and the evaluation system are provided, in which the reverse bias current property (leakage property) is evaluated while monitoring the charging state on the surface of the plug connected to the device in the wafer on which the semiconductor devices in the course of the manufacturing process are fabricated.

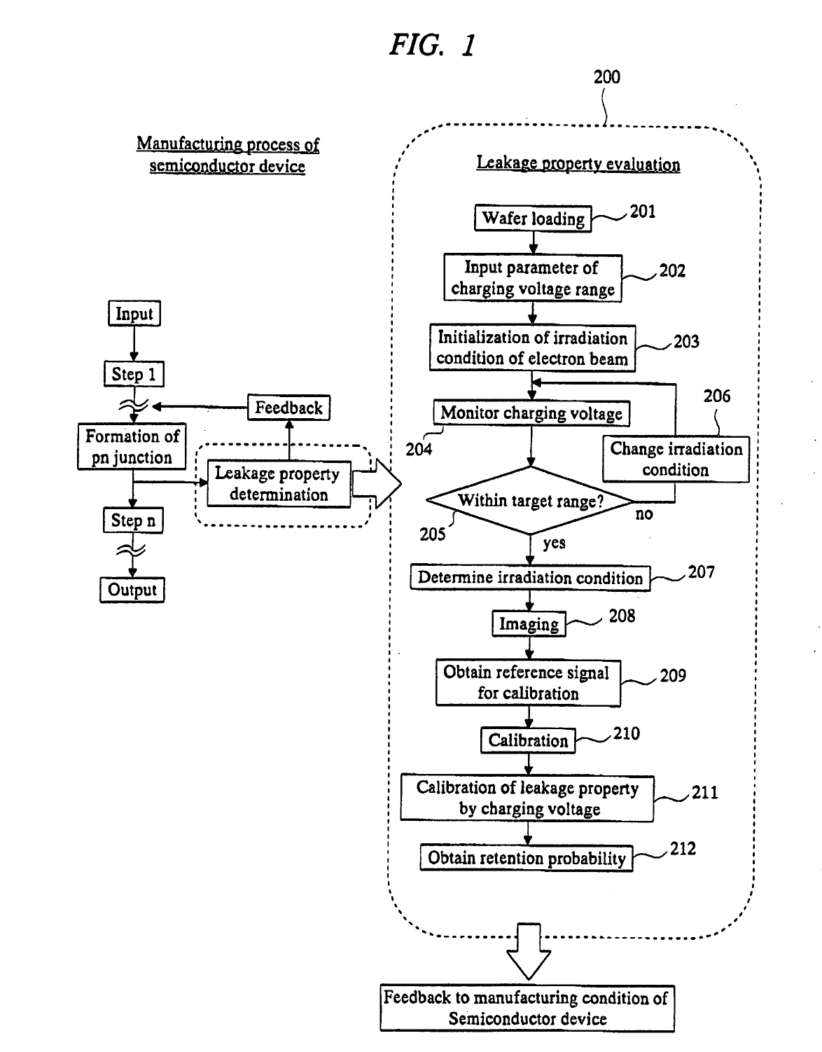

First, the flow of the evaluation method of the leakage property of a semiconductor device according to this embodiment will be described in brief. FIG. 1 shows the flow of the method. After inputting a wafer into the semiconductor manufacturing apparatus, the process is started from the step 1. When the step of forming the pn junction is finished, the wafer on which the plugs are exposed is taken out, and the main evaluation 200 is started. First, as a step 1 (201), the wafer on which the pn junction has been formed is loaded (carried) in the evaluation system. Then, as a step 2 (202), a desired charging voltage range of the plug surface is set. The way to determine the desired value will be described later. Next, as a step 3 (203), the irradiation condition of the electron beam in the evaluation system is set to the first irradiation condition, and as a step 4 (204), the electron beam is irradiated to the wafer to monitor the charging voltage generated on the plug surface. As a step 5 (205), it is determined whether the monitored result is within the desired range of the charging state. If it is within the desired range, as a step 7 (207), the irradiation condition of the electron beam is fixed, and as a step 8 (208), the evaluation of leakage property is started. If it is not within the range, as a step 6 (206), the irradiation condition of the electron beam is changed and the flow returns to the step 4 (204) to monitor the charging voltage again. When it is confirmed that the charging voltage is within the desired range after the monitoring process and the feedback process of the steps 4 to 6 are repeated, the irradiation condition of the electron beam is fixed in the step 7 (207) and the flow proceeds to the evaluation of the leakage property in the step 8 (208). In the evaluation of leakage property, the electron beam is irradiated several times to the position to be evaluated so as to generate the secondary electrons, and then, an image thereof is formed. By extracting the contrast signal showing the brightness of the image, the data as the leakage property in the position where the electron beam is irradiated on the wafer is obtained. Then, as a step 9 (209), the beam is irradiated to the two types of samples for contrast calibration under the same condition as that of the property evaluation to acquire the secondary electron signal. The two samples for calibration are, for example, a sample having electrical conduction to the sample holder on which a wafer is mounted and a sample having no electrical conduction thereto. Thereafter, as a step 10 (210), the result of the leakage property evaluation is calibrated by using the reference signal. Furthermore, as a step 11 (211), the evaluation result is translated into the leakage property in the voltage state of the semiconductor device operated actually based on the result of the charging voltage on the surface of the plug obtained in the step 4 (204). Then, as a step 12 (212), the absolute value of the leakage property in the actual operation of the semiconductor device is obtained. Through the series of steps, the junction leakage property of the semiconductor device can be evaluated in the course of the manufacturing process.

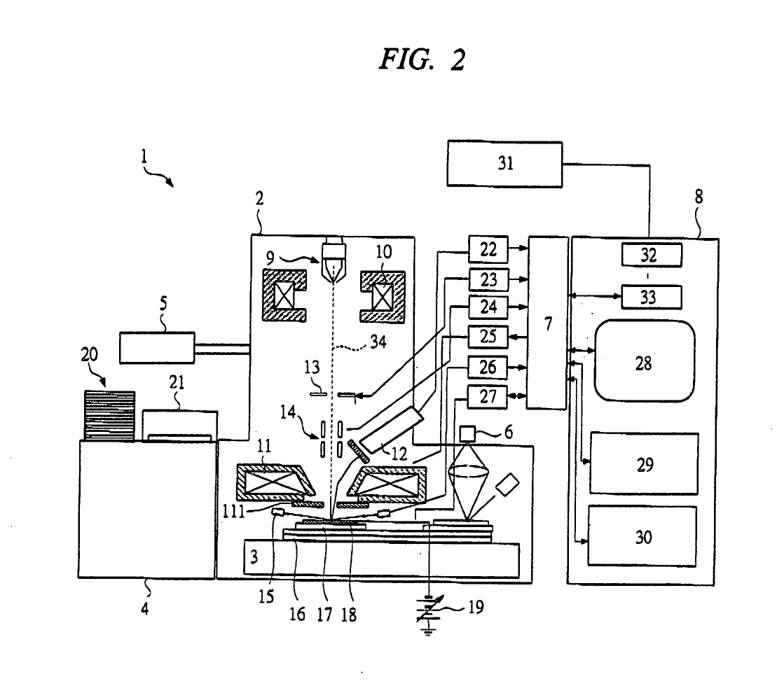

FIG. 2 shows the structure of the evaluation system of a semiconductor device according to this embodiment. The evaluation system of a semiconductor device (inspection system) 1 comprises an electron beam irradiation system (electron beam optics) 2, a stage mechanical unit (stage unit) 3, a wafer handling unit 4, a vacuum unit 5, an optical microscopy 6, a control unit 7 and an operation unit 8.

The electron beam irradiation system 2 is provided with an electron gun 9, condenser lenses 10, objective lenses 11, a detecting unit (detector) 12, a blanking deflector 13, deflectors 14, a wafer height detector (height measure sensor) 15 and charge control electrodes 111.

The stage mechanical unit 3 is provided with a XY stage 16 and a holder 17 (sample stage) on which a wafer is mounted and a retarding power supply 19 for applying negative voltage to the holder 17 and the wafer 18. A position detector by the laser length measurement is attached to the XY stage 16. Note that a reference sample piece for calibration and a Si bare wafer piece are attached to the edge of the holder.

The wafer handling unit 4 is provided with a wafer case hold unit 20 and a wafer loading/unloading unit 21. The wafer holder 17 goes back and forth between the wafer loading/unloading unit 21 and the XY stage 16 while mounting the wafer 18 thereon.

The control unit 7 is provided with a signal detection control unit 22, a blanking control unit 23, a beam deflector control unit 24, an electron beam optics control unit 25, a wafer height measurement unit (height detector) 26 and a mechanical/stage control unit (stage control unit) 27.

The operation unit 8 is provided with, as the signal processing means, a graphical user interface and user interface unit 28, an image processing unit 29, an image/inspection data storage unit (data storage unit) 30, a data input unit 32 for transmitting data from an outer server 31 and a data translate unit 33.

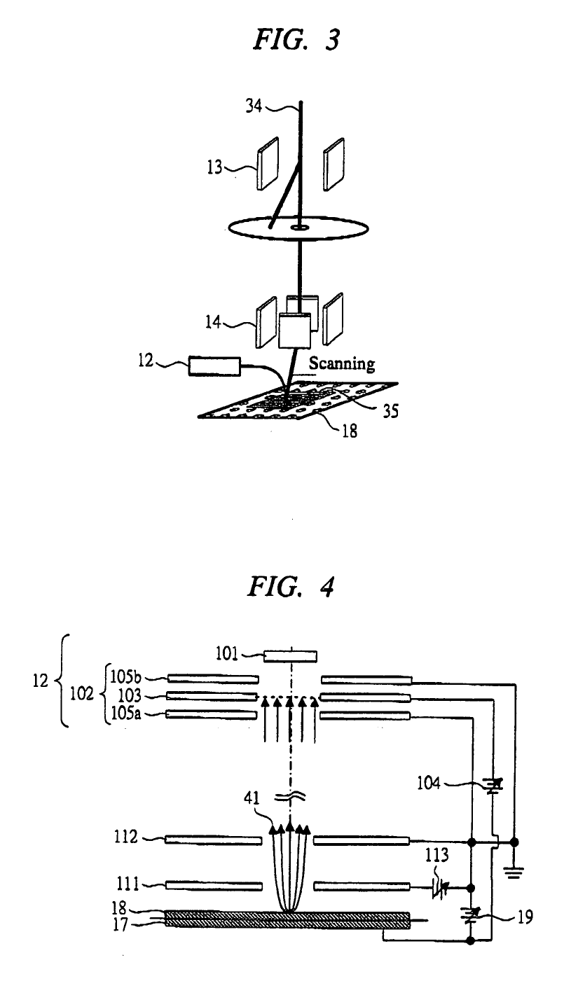

FIG. 3 is an enlarged view showing the electron beam optics 2. The timing of the irradiation of a primary electron beam 34 to the wafer 18 is controlled by the blanking deflector 13. When irradiating the electron beam to the wafer 18, the scanning speed and the beam scanning area 35 thereof are controlled by the deflector 14, and the signals are detected by the detector 12 in accordance with the scanning speed.

FIG. 4 shows the arrangement of the electrodes adjacent to the wafer to be a sample and those around the detection system. The charge control electrodes 111 and electrodes in a ground state (ground electrode) 112 are provided above the wafer 18 to be a sample, and are opposed to the sample wafer 18. The wafer 18 to be a sample is mounted on the sample holder (sample stage) 17 and the wafer 18 and the sample holder 17 have electrical conduction to each other. As described above, the retarding power supply 19 is connected to the wafer 18 and the holder 17, and a power supply 113 capable of applying an arbitrary voltage is connected to the charge control electrode 111. In this structure, a desired voltage distribution is generated on the wafer by the wafer 18 to be irradiated with the electron beam, the holder 17 on which the wafer 18 is mounted, the charge control electrodes 111 and the ground electrodes 112, and the energy of the primary electron beam and the voltage gradient near the wafer can be adjusted to the predetermined conditions.

The detection system 12 is provided with a detector 101 and an energy filter 102 placed in front of the detector 101, and the filter 102 includes filtering electrodes 103, a filter power supply controller 109 and electrodes of ground voltage 105a and 105b. The energy filter 102 with the structure described above blocks the penetration of the low energy part of the secondary electrons generated from the wafer by applying a desired voltage from the filter power supply controller 104.

Next, the evaluation method of reverse bias current (leakage current) of a semiconductor device, in particular, a DRAM (Dynamic Random Access Memory) by using the system with the above-described structure will be described.

In the DRAM, one memory cell is composed of one transistor called MOSFET and one charge storage capacitor (capacitor), and the information is recorded therein by storing electric charge in the capacitor. In the capacitor, a pn junction portion is provided below the contact plug to the capacitor in order to maintain the stored data by applying the reverse bias voltage to retain the charge. However, since a weak current (reverse bias current, leakage current) passes through the pn junction portion even at the time of the reverse bias application, the charge is inevitably reduced after a predetermined time. Therefore, the data retention operation is performed in the DRKM at time intervals in which the reduction of the charge does not cause any problems. In the normal plugs, the reduction of the charge at the time intervals of the data retention operation is within the tolerable range, and the stored data can be maintained. Meanwhile, if the abnormal pn junction in which the charge is leaked in a significantly short time is present, the data in the bit is not maintained. Therefore, the time in which the charge in the charge storage capacitor is lost by the reverse bias current (leakage current) in the pn junction of each bit, that is, the data retention time is the important data showing the performance of the DRAM. For this reason, as a procedure for the quality management of the DRAM, the electric test for the completed wafer is executed to examine the data retention time.

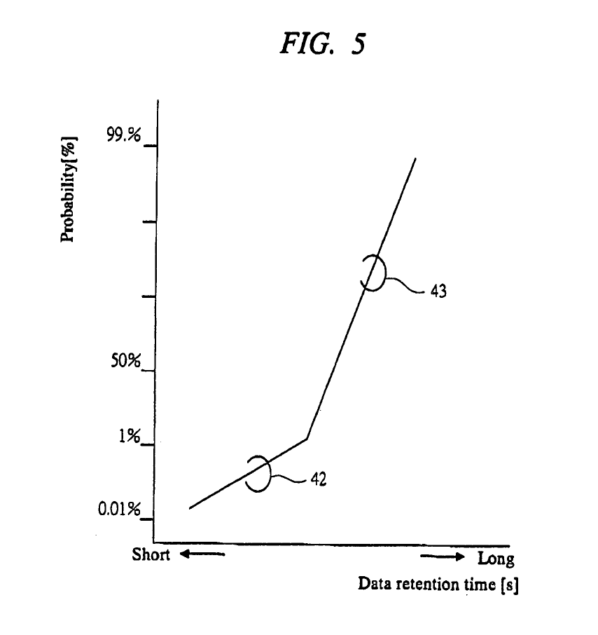

As an example of the inspection result of the data retention time, the probability distribution of the data retention time measured in a certain test sample is shown in FIG. 5. FIG. 5 is a lognormal probability distribution in which the horizontal axis represents the data retention time and the vertical axis represents the probability. The distribution of the data retention time includes two parts such as a main profile 43 made of a large number of bits with an average leakage property and a tail profile 42 made of a small number of abnormal bits with high leakage current, that is, leakage failure bits. For the quality management of the DRAM and the reduction of the development period thereof, it is necessary to accurately grasp them in an early stage. Particularly, for the development of the high-quality semiconductor products in a short period, it is very important to accurately grasp the occurrence frequency and the leakage amount of the tail profile 42 in an early stage and to give the feedback to the process condition so as to take measures quickly. For its achievement, the present invention provides the technology for nondestructively evaluating the leakage property in a noncontact manner in the course of the process before the completion of the final process. Therefore, the electron beam is irradiated to the wafer in the course of the process to form the reverse bias voltage state in the pn junction, and then, the leakage property is acquired from the obtained secondary electron signals. Hereinafter, the evaluation method of the leakage property will be described below.

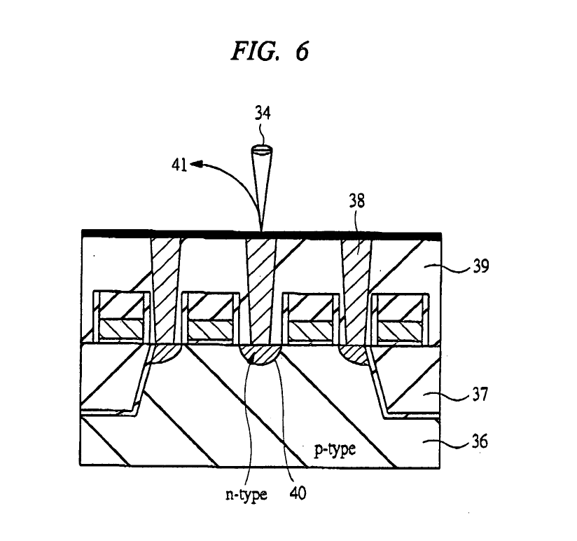

FIG. 6 is a conceptual diagram showing the action in the case where the primary electron beam 34 is irradiated to the wafer after the steps of forming the pn junction and embedding the plugs of the DRAM. In the structure of the sample, isolation layers 37 are formed on a substrate 36, and each of the transistors is isolated by the isolation layers 37. In the part of the transistor, hole patterns in which the plugs 38 are embedded are formed, and the plugs 38 are surrounded by the interlayer insulator layer 39. Also, the pn junction 40 is formed below the plug 38. In this embodiment, a p type substrate is used as the substrate, and a polysilicon film doped with n type ion is used as a plug material.

As described above, the electron beam is irradiated to the wafer to apply the reverse bias voltage to the pn junction. Therefore, in the pn junction portion in which a n type layer is formed as an upper layer and a p type layer is formed as a lower layer as shown in FIG. 6, it is necessary to apply the positive voltage to the wafer surface. Therefore, the irradiation condition of the primary electron beam 34 is set so that the yield efficiency δ of the secondary electron 41 generated when irradiating the primary electron beam 34 to the wafer satisfies the condition of δ>1. The yield efficiency of the secondary electron indicates the ratio of the number of secondary electrons to the number of electrons of the irradiated electron beam. Since the yield efficiency δ of the secondary electron depends on the irradiation energy of the primary electron beam, the beam is irradiated at 500 eV in this embodiment, which can set the SE yield δ to about 1.1 to 1.2. Consequently, when the primary electron beam is irradiated, since SE yield δ is larger than 1, a number of secondary electrons which are larger than that of the irradiated electrons are emitted, and the positive charges become excessive on the surface of the plug 38. Since the pn junction 40 is provided between the plug 38 and the substrate 36 and the pn junction 40 is put into the reverse bias state, the electron supply from the substrate 36 to the plug 38 is extremely small, and the plug 38 is positively charged.

In this embodiment, the irradiation energy of the primary electron beam 34 is adjusted in the following manner. First, the primary electron beam 34 is accelerated to about several kev immediately after outputting from the electron source, and the beam is brought to the position above the objective lens from the electron gun while maintaining the accelerated state. As shown in FIG. 4, the electrodes in a ground state (ground electrode) 112 are provided near the wafer so as to be opposed to the wafer 18, and the negative voltage (retarding voltage) Vr is applied to the holder in contact with the wafer 18. By doing so, the electric field in which the primary electron beam 34 is rapidly decelerated near the wafer 18 is formed to decelerate the beam 34. When the irradiation energy-is set to 500 eV, the retarding voltage Vr is set so that the difference between the initial acceleration voltage of the primary electron beam 34 and the retarding voltage Vr of the sample 18 becomes 500 eV.

Also, as a parameter for adjusting the charging state on the plug surface to the desired state other than the irradiation energy of the primary electron beam 34, the voltage gradient on the wafer is changed. On the wafer 18, as shown in FIG. 4, the charge control electrodes 111 are provided between the wafer 18 and the ground electrode 112, and the electric field of the voltage gradient near the wafer 18 is formed by the wafer 18, the charge control electrode and the ground electrode 112. In this embodiment, the voltage Vcc (Vcc>Vr) is applied between the wafer 18 and the charge control electrode 111 from the power supply 19 so that the charge control electrode 111 becomes relatively positive voltage, and the electric field which accelerates and extracts the secondary electrons 41 from the wafer 18 is formed. At this time, when the voltage gradient of the acceleration field is changed, the height of the voltage barrier on a wafer and the voltage state are changed. As a result, the charging voltage on the wafer surface is changed. The charging voltage of the sample 18 is adjusted by controlling the voltage Vcc of the charge control electrode 111. Furthermore, the charging is varied also by the current amount of the primary electron beam 34. The charging voltage of the plug surface is adjusted to the desired range by changing the conditions described above.

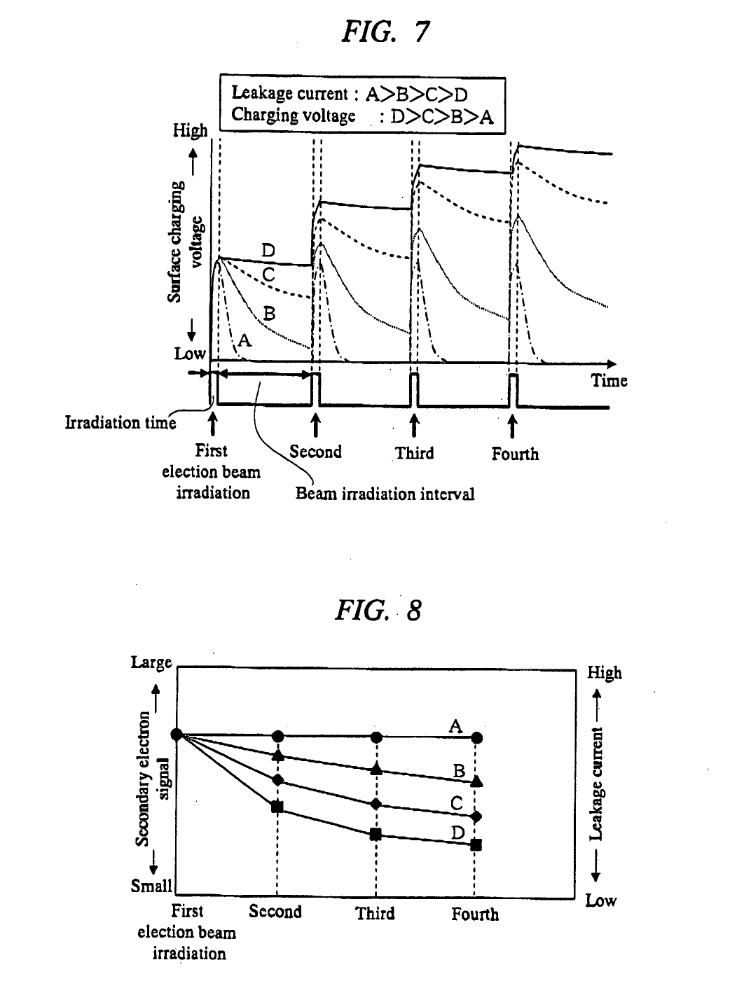

In the reverse bias voltage state formed in the manner described above, the electron beam is intermittently irradiated several times to the sample in this embodiment in order to evaluate the reverse bias current. FIG. 7 shows the state in which the charging voltage is relaxed when the electron beam is irradiated several times to the same plug. The vertical axis represents the charging voltage on the plug surface and the horizontal axis represents the time. The reference symbols A, B, C and D shown in FIG. 7 indicate the reverse bias current (leakage current) and are in a relation of A>B>C>D. As shown by A in FIG. 7, in the case of the junction in which the reverse bias current is high, the charge is completely relaxed within the beam irradiation interval. On the other than, as shown by B, C and D in FIG. 7, along with the reduction of the reverse bias current, the charge relaxation time is increased, and since the next electron beam irradiation is started before the charge is completely relaxed, the voltage is increased by irradiating the electron beam several times. As a result, in the process of irradiating the electron beam several times, the charging voltage on the plug surface is higher in the order of D>C>B>A.

In this charging state, the change in the secondary electron signal amount emitted from A, B, C and D is shown in FIG. 8. In general, the secondary electron signal amount and the charging state and the voltage contrast are in the relation as follows. When the beam is irradiated to the wafer surface and the voltage difference is generated between the positively charged position and the peripheral portion thereof which is not charged, a voltage saddle point is formed above the charging point due to the difference in voltage. The saddle point functions as a barrier and the secondary electrons from the charging point are partly brought back to the wafer. As a result, the secondary electrons are brought back more in the part where the charging amount is large, and the image becomes dark. As described above, the charging state of a wafer is reflected on the secondary electron signals, and the image is formed as the voltage contrast. Therefore, in the case of A in which the reverse bias current is high, since the charging voltage is low, the secondary electron amount is large, and the image becomes bright. Along with the reduction of the reverse bias current from B to C and D, the charging voltage is increased. Therefore, the secondary electron signal amount is reduced and the image becomes darker. Then, by extracting the secondary electron signal amount from each of the plugs, the leakage property of each plug can be grasped. If the secondary electron signal amount is obtained from a large number of plugs in the same manner to measure the frequency distribution thereof, the main profile and the tail profile of the leakage property of the DRAM to be evaluated can be easily grasped.

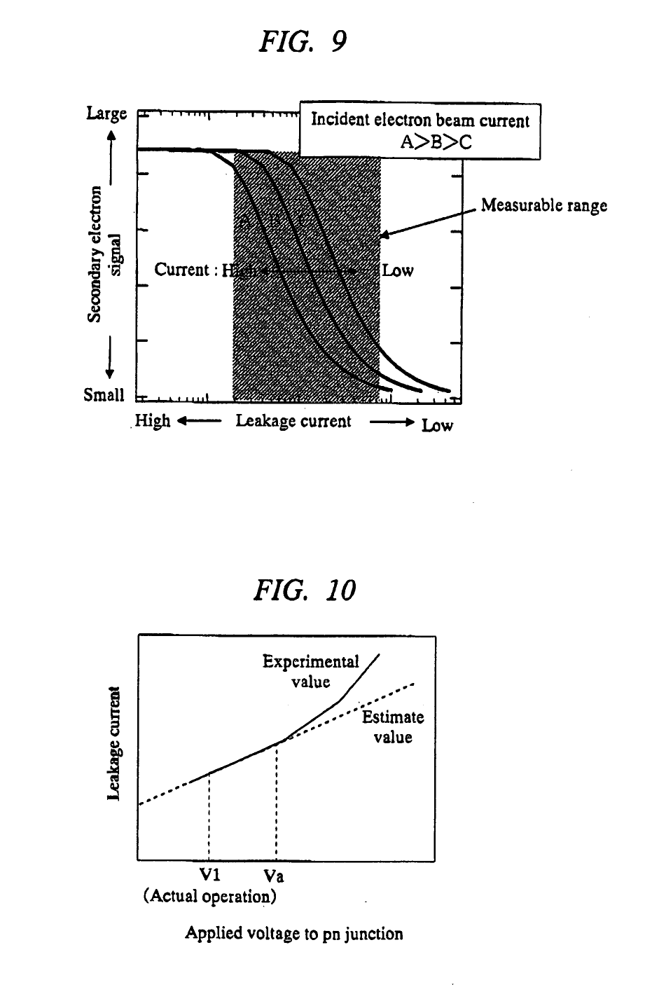

Furthermore, FIG. 9 shows the relation among the incident beam current amount irradiated to the wafer, the leakage current in the junction portion, and the secondary electron signal amount. The incident electron beam current is in a relation of A>B>C in FIG. 9. As shown by the hatching, there is the area in which the secondary electron signal is largely changed in the specified range of the leakage current, that is, there is the measurable range suitable for the measurement. When the electron beam current is reduced from A to B and C, the measurable range shits to the area with the low leakage current. By making use of this relation, the leakage property evaluation in a desired level can be realized by selecting the electron beam current having the measurable range in the desired leakage current level.

However, the leakage property obtained by the method described above has the technical problem described below. When the DRAM products are operated, a predetermined reverse bias voltage V1 is applied to the pn junction portion. The weak leakage current (reverse bias current) in the normal bit in the actual operation is defined as IL1. On the other hand, when the reverse bias state is formed by irradiating the electron beam in accordance with the evaluation method, the voltage V2 which is different from the voltage V1 applied in the actual operation may be applied to the junction portion. In the case where the voltage V2 applied to the junction during the evaluation is significantly higher than the voltage V1 (V2>>V1), the leakage path is formed even in the bit which is originally a normal bit and the leakage current IL2 is extremely increased in some cases; More specifically, the normal bit acts like the abnormal bit. Therefore, when the voltage applied to the junction which is being evaluated is increased too much, there is the possibility that the main profile and the tail profile of the leakage property of the DRAM obtained from the evaluation result do not correctly reflect the distribution in the actual operation. That is, when the voltage applied to the junction portion is unknown, it is unclear whether or not the evaluation result of the leakage property distribution is accurate. In addition, when the voltage applied to the junction portion is unknown, it is difficult in principle to translate the obtained leakage property distribution into the leakage property distribution in the actual operation.

In such a circumstance, as a result of the examination for I/V characteristics of the device and the comparison of the result thereof with the logical calculus, as shown in FIG. 10, it is found out that the leakage current is proportional to the voltage V applied to the junction until a certain limit voltage Va (Va>V1), and it is placed on the same straight line as the leakage current in the actual operation. More specifically, it has been found out that the so-called acceleration test can be executed until the certain voltage Va. When the voltage higher than Va is applied, the leakage current becomes higher than the estimate value, and the high leakage current may be generated even in the normal pn junction portion. The present invention focuses attention on that point for the first time, and it provides the evaluation method including the feedback step in which the voltage applied to the junction is measured and monitored so as not to exceed a predetermined range and the electron beam irradiation condition is changed so as to apply the voltage within a predetermined range.

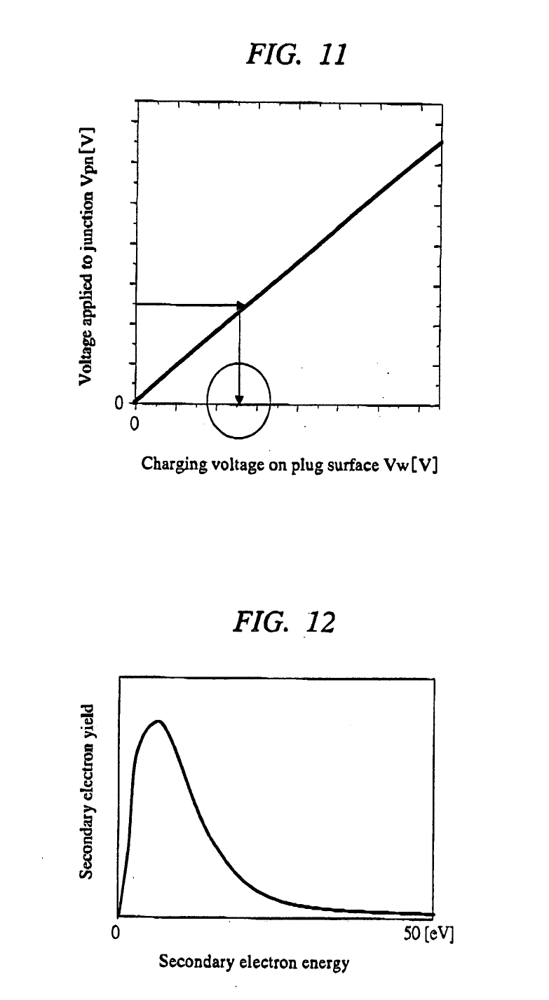

Since it is difficult to directly measure the voltage applied to the junction in a noncontact manner, the present invention focuses attention on the voltage difference between the plug layer and the lower layer which can be directly measured, that is, the charging voltage Vw on the plug surface, and the relation of the voltage Vpn applied to the pn junction and the voltage Vw is examined. As a result, it can be discovered that the relation between the voltage Vw on the plug surface and the voltage vpn applied to the junction can be obtained as shown in the example of FIG. 11 by modeling the generation of the charge with separating into the pn junction portion and the underlying portion thereof and calculating a solid-state data such as the junction capacitance of the device. More specifically, if the charging voltage on the plug surface can be obtained, the voltage Vpn applied to the junction can be calculated. Therefore, in this embodiment, after the charging voltage Vw on the plug surface is measured, the voltage Vpn applied to the junction is calculated from the charging voltage, and it is evaluated whether the voltage Vpn is within the desired range.

Note that, when the solid-state data of the device is insufficient, it is difficult to grasp the relation between the charging voltage Vw on the plug surface and the voltage Vpn applied to the junction. In such a case, if the irradiation condition in which the charging voltage Vw to the plug surface becomes almost equal to the upper limit Va of the voltage applied to the junction is selected, since the voltage Vpn applied to the junction is lower than the voltage Vw, the Vpn is certainly lower than Va and it is possible to satisfy the desired condition. In this manner, it is possible to confirm whether the voltage is within the desired voltage range even when the device structure is unknown.

In addition, in the case of the device as shown in FIG. 10 in which the I/V characteristics are unknown, the upper limit Va of the voltage applied to the junction is set to the value equal to the voltage V1 in the actual operation or the value as close as possible to the voltage V1 and then the evaluation is executed.

Next, the method of measuring the charging voltage Vw on the plug surface will be described. The secondary electrons generated from the plug surface are accelerated and brought upward by the electric field formed by the wafer 18, the charging control electrode 111 and the ground electrode 112 as shown in FIG. 4. The accelerated and brought secondary electrons 41 are deaccelerated by the energy filter 102 in front of the detector. By changing the voltage VEF of the energy filter 102, the low energy part of the secondary electrons 41 cannot pass through the filtering electrode 103.

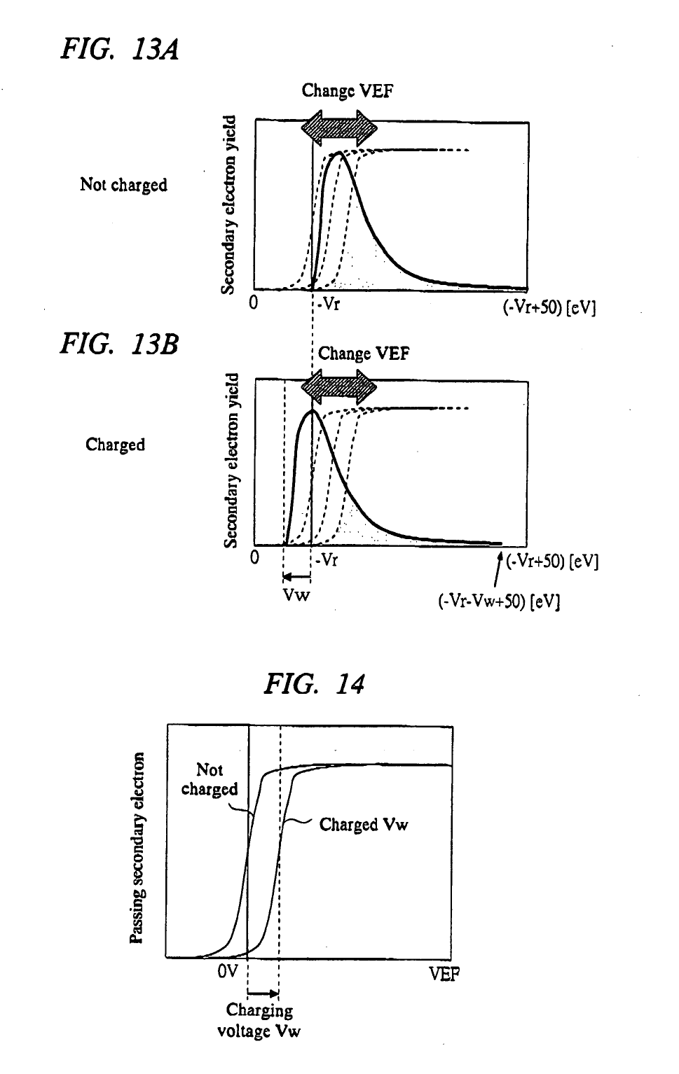

As shown in FIG. 12, the secondary electrons 41 are generated with the energy of 0 to 50 eV from the wafer 18 to be the sample. The vertical axis of FIG. 12 represents the secondary electron yield. Since the acceleration field is formed on the sample, the energy of the secondary electrons after passing through the acceleration field is increased by e·(0−Vr) (e: elementary charge) [ev]. More specifically, as shown in FIG. 13A, the energy of the secondary electrons is distributed within the range from e˜(0−Vr) [eV] to e·(50−Vr) [eV]. The Vr is the negative voltage applied to the sample. In addition, when the sample is partly charged with the positive voltage Vw (Vw>0 V) relative to the Vr, as shown in FIG. 13B, the energy increase of the secondary electron generated from the charging area after passing through the acceleration field is changed to e·(0−(Vr+Vw)), and the distribution is shifted to the low energy side. When detecting the secondary electron, the voltage (Vr+VEF) is applied to the filtering electrode in front of the detector and the passage of the low energy part of the secondary electrons is blocked. Therefore, only the electrons within the area shown by the hatching are detected. The examples of the characteristic curves showing the ratio of the secondary electrons blocked by the energy filter ate shown by the dotted lines in FIG. 13A and FIG. 13B. In the case where the ideal energy filter is used, the characteristic curve becomes the step function which vertically straightens up from 0 to 100%. When the VEF of the energy filter is changed to change the number of secondary electrons to be passed, the S-shaped curve as shown in FIG. 14 can be obtained. Also, since the energy distribution of the secondary electron is shifted depending on the charging voltage in the position where the secondary electrons are generated, the S-shaped curve is also shifted. By measuring the amount of shift of the S-shaped curve, the shift amount is obtained as the charging voltage of the sample. In this embodiment, based on the principle described above, the voltage VEF of the energy filter is changed and the images of the pattern portion and the conducting portion are taken so as to obtain the S-shaped curves. Then, by comparing them, the charging voltage Vw is measured.

When it is determined whether the measured charging voltage is within the desired range and it is confirmed that the voltage is within the desired range, the irradiation condition of the electron beam is fixed and the leakage property evaluation is started. In the leakage property evaluation, the energy filter is turned off (OFF) so as to detect all of the secondary electrons directed to the detector, and the secondary electron signals are acquired.

The amount of secondary electron signals acquired here corresponds to the value of the gray level showing the brightness of the digitalized image. In this embodiment, the analog signals of the secondary electrons detected by the detection system are A/D converted into the 256 gray levels. Therefore, the acquired signals are not the absolute values of the voltage and the current but the relative values, and have the characteristics that the scale of the value is varied depending on the various conditions of the system used for the data acquisition. The various conditions include, for example, the slight difference in daily adjustment of the electron beam optics, the condition of contrast adjustment and the difference in each system. In this technology, the establishment of the method capable of translating the relative data into the directly comparable data with the same scale even if various conditions such as the system, the experimental date and the adjustment state are different, that is, the establishment of the data calibration method is the very important object.

The basic concept for the data calibration in the present invention will be described. FIG. 9 shows the relation between the leakage current of the pn junction below the plug and the secondary electron signals obtained from the plug surface. As is understood from FIG. 9, when the leakage current is sufficiently larger or smaller than the measurable range of the evaluation, the secondary electron signal amount becomes the maximum value and the minimum value, respectively. The present invention focuses attention on this point, and the samples with the resistance value much lower and higher than the resistance value in the reverse bias state of the pn junction below the relevant plug are prepared, and the secondary electron signals of the samples are obtained and set as the reference signals. For example, a piece of Si (Si bare wafer) with an unprocessed substrate is used as the sample with a low resistance, and an oxide film (SiO₂ film) formed between the plugs is used as the sample with a high resistance. The signals obtained from them are set as the maximum value Smax and the minimum value Smin of the secondary electron signal, and the signal S from the relevant plug is calibrated in accordance with the expression below to obtain the calibrated signal amount Sr.
Sr=(S−Smin)/(Smax−Smin)

Furthermore, since the temperature and the applied voltage in the device being evaluated are different from those of the actual operation, it is necessary to translate the obtained leakage property distribution into the leakage property distribution under the actual operation conditions. For this translation, it is preferable to prepare the translation table obtained through the examination of the I/V characteristics of the device and the temperature dependency of the retention property or to perform the logical calculus. Since the voltage applied to the pn junction being evaluated is known, it is possible to perform the accurate translation into the actual operation.

The basic concept and principle of this embodiment have been described above.

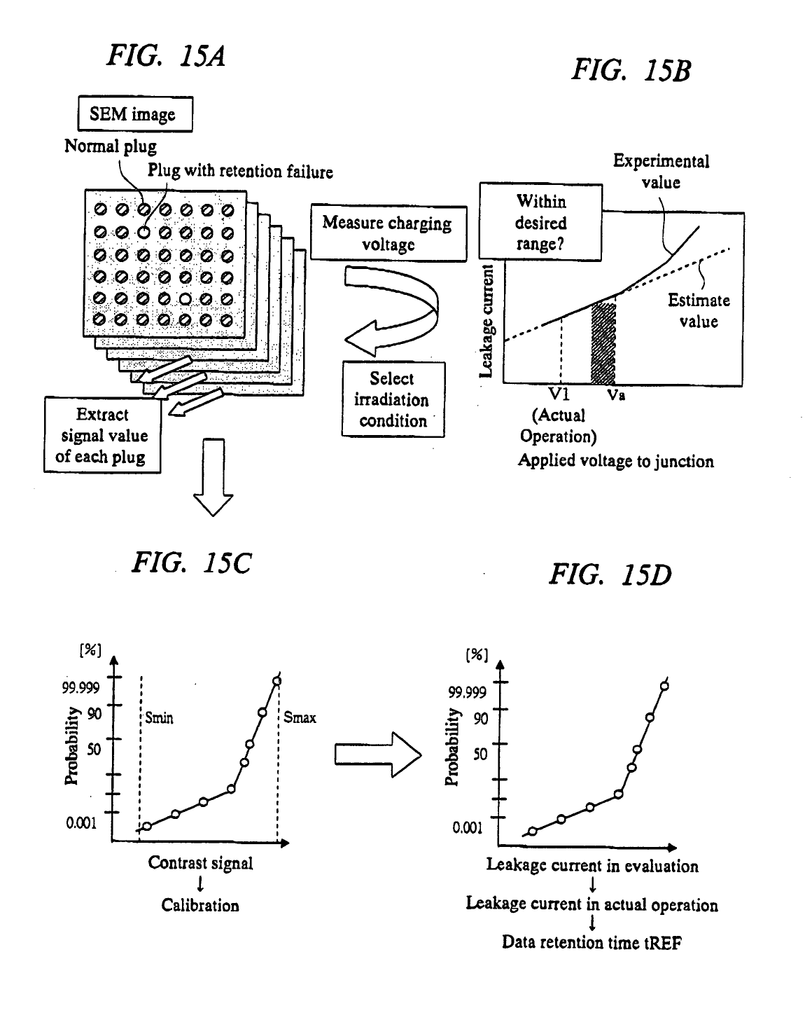

Next, the procedure of the leakage property evaluation will be concretely described. FIG. 1 shows the overall flow of the evaluation, FIG. 15 shows the flow from the step of taking the image of the wafer 18 to be inspected to the step of evaluating the junction leakage property of a wafer, and FIG. 2 shows the whole structure of the system.

A wafer of the semiconductor product just after the steps of forming a pn junction, embedding plugs and polishing for planarization is taken out and carried to the evaluation system according to this embodiment. After mounting the wafer on an arbitrary rack of a wafer case, the case is placed on the wafer case hold unit 20 in the wafer handling unit 4 shown in FIG. 2. Next, the rack number in the case which indicates the wafer to be evaluated is designated from the graphical user interface/user interface unit 28, and the designated wafer 18 is carried into the evaluation system 1. The wafer to be inspected 18 is mounted on the holder 17 through the wafer case hold unit 20 and the wafer loading/unloading unit 21 including the arm and the spare vacuum chamber. Then, after it is held and fixed, it is subjected to the vacuum evacuation together with the holder in the wafer loading/unloading unit 21, and then, it is carried into the sample chamber which has been already evacuated by the vacuum unit 5.

When the wafer 18 is loaded, the irradiation condition of the primary electron beam 34 to the wafer 1 and the evaluation condition are inputted from the graphical user interface. First, the voltage range of the voltage capable of being applied to the pn junction formed on the wafer during the evaluation is inputted. The maximum value of the voltage range is the voltage value Va0 which is larger than the voltage V1 applied to the junction in the actual operation and becomes the upper limit capable of executing the acceleration test, and in which the relation between the leakage current and the applied voltage has the same proportional relation as the property in the actual operation. More specifically, |Va0|>|V1|. The Va0 is calculated in advance from the physical data of the wafer to be evaluated, or the value thereof is obtained through a procedure such as the evaluation and estimation of the I/V characteristics. Also, in order to calculate or estimate the voltage Vpn applied to the lower pn junction when the charging voltage Vw on the plug surface is obtained, the physical data of the pn junction and that below the junction are prepared in advance or are inputted on the spot. Alternatively, they are calculated or estimated by using a simple calculating expression or preparing a numerical table. In this manner, the maximum value Va (|Va|>|Va0|>|V0|) acceptable as the charging voltage on the surface is determined. Also, as described above, when the solid-state data of the device is insufficient, the charging is made so as to set the charging voltage Vw of the plug surface to be lower than Va0. In such a case, since the voltage lower than Va0 is automatically applied to the junction portion, the charging is within the desired range, and the predetermined condition can be satisfied. In the DRAM examined in this embodiment, the voltage applied to the pn junction in the actual operation is estimated to be 3 V and the upper limit capable of executing the acceleration test is estimated to be 5 V.

Next, the initial value of the irradiation condition of the electron beam is set. At this time, the desired leakage current level to be evaluated is first estimated in advance, and the beam current with the measurable range for this range of the leakage current is set as shown in FIG. 9. In this case, the leakage of 1×10⁻¹⁵ to 1×10⁻⁹ [A] is first estimated, and the irradiation energy of the beam is set to 500 eV and the beam current is set to 50 pA so that the secondary electron yield can be about 1.1. The settable minimum voltage value which is positive to the wafer is set to the charge control electrode as an initial value. In this manner, the state where the charging is inhibited to some extent is formed.

Also, the number of additions of the image frame, the weighting in the addition and the magnification of the image are set to desired values. As an example of the image frame addition and the weighting, the number of frame additions n max is set to 32 and the weighting of the additions w (n) is set to w=0 (n=1), w=1 (2≦n≦32). More specifically, in the case where the signal of image frame on the n th irradiation is defined as Sn, the arithmeetic processing is executed so that the addition result S_sum can be expressed by the following expression.

$$\begin{matrix}S\_sum = \frac{{\sum }_{n = 1}^{n max} [ Sn \times w ( n ) ]}{{\sum }_{n = 1}^{n max} w ( n )} \\ = \frac{S1 \times 0 + ( S2 + S3 + … + S32 ) \times 1}{31}\end{matrix} \qquad Expression 1$$

The reason why the first frame signal is multiplied by 0 and is excluded from the addition is as follows. That is, as shown in FIG. 8, the numbers of secondary electrons generated from the plugs on the pn junctions each having different leakage currents are almost equal to each other in the first irradiation in principle, and the difference in number is found from the second irradiation. Therefore, in this embodiment, the signals of the first irradiation are ignored and only the image signals of the second and subsequent irradiations in which the difference becomes obvious are used. However, other than this embodiment, it is also possible to adopt all of the frame signals from the first to n max th irradiations by setting all weighting to 1 for simplification. In this case, since the image frame of the first irradiation is also added, the difference in leakage becomes unclear in comparison with that of this embodiment. However, the difference in leakage is reflected on the addition result to some extent by the signals of the image frame of the second to 32nd irradiations. Alternatively, it is also preferable that the weighting is increased along with the increase of the number of irradiations. In this case, the difference in the secondary electron signals due to the difference in leakage can be reflected on the addition result more obviously.

After determining the irradiation condition, the evaluation position of the wafer to be evaluated is determined. That is, the desired chip to be evaluated on the wafer is set, and the imaging pitch and the number of images are set.

The input conditions described above are transmitted to each unit and set by the electron beam optics control unit 25. When the input of the irradiation condition is finished, the irradiation of electron beam from the electron beam optics is started. First, the stage is moved so that the electron beam is irradiated to, for example, the reference sample piece. Then, the axis of the beam is aligned and beam calibration such as the focal point/astigmatic adjustment is performed. At the same time with the beam alignment, the height of the wafer 18 is obtained by the height detector 15, and the correlation between the height data and the focused focal point conditions of the electron beam is obtained by the wafer height measurement unit 26. By doing so, it becomes possible to make an automatic adjustment to the focused focal condition based on the detection result of the wafer height without performing the focusing in the subsequent acquisitions of electron beam images. Therefore, it becomes possible to obtain the secondary electron images quickly and consecutively.

Next, after the stage is moved so that the electron beam is irradiated to the predetermined position on the wafer to be inspected 18, the electron beam image of the wafer 18 is obtained and the contrast and the others are adjusted. The contrast and brightness of the image are automatically adjusted so as to maximize the contrast by selecting the “contrast/brightness automatic adjustment” mode. After it is confirmed that the desired contrast is obtained by the operation of the “automatic adjustment” mode, the “contrast/brightness fixing” mode is selected to fix the parameters of the contrast and the brightness. Therefore, it becomes possible to obtain a large number of images with the same contrast and brightness conditions.

Next, the energy filter is operated to measure the charging voltage on the plug surface of the wafer to be evaluated. The procedure of the voltage measurement has been described above. More specifically, the secondary electron images are obtained with changing the filter voltage VEF and the positions thereof, and then, the images are stored. For the comparison purpose, the stage is moved so that the electron beam is irradiated to the Si bare chip piece mounted on the edge of the holder, and the secondary electron signal is similarly obtained with changing the filter voltage VEF. With respect to the secondary electron signals from the wafer to be evaluated, the signal amount of each plug portion to be evaluated is extracted and averaged. With respect to the signals from the Si bare wafer, the average of the signals of a proper pixel size, for example, 200×200 pixels is obtained. The graph in which the data obtained from both samples is represented as a vertical axis and the VEF is represented as a horizontal axis is formed, and the S-shaped curves obtained from both samples are compared to obtain the charging voltage Vw. Thereafter, it is determined whether or not the charging voltage Vw is higher than an allowable value Va by the comparison operation.

When the charging voltage Vw is higher than the allowable amount Va as a result of the comparison, after the irradiation energy of the electron beam and the election beam irradiation conditions such as the charging control electrode voltage are changed to further inhibit the charging, the beam alignment, the height adjustment and the charging voltage measurement by the energy filter are performed again. This process is repeated and the irradiation conditions of the electron beam are changed until the charging voltage is reduced to the desired charging range. In this case, if the charging on the wafer surface remains large and it is necessary to remove the previous charging before the next irradiation under the changed conditions, it is possible to relax the charging by irradiating ultraviolet ray or irradiating the electron beam with different irradiation conditions, though not shown.

In addition to the inhibition of the charging and the determination whether or not the voltage is lower than the upper limit of the allowable range, it is also necessary to confirm whether or not the image quality such as contrast and noise is sufficiently good. When the charging is too low, the voltage contrast at the plug portion becomes low, and the good image of the plug cannot be obtained in some cases. Also, due to the low contrast, the relatively large noise of the image is detected and the image quality is degraded in some cases. Since the technology of the present invention is characterized in that a large number of images are analyzed and the leakage property distribution of a large number of patterns is evaluated through the statistical processing, the good image quality is the essential requirement. When the image quality is not good, the number of additions of images is increased. Alternatively, the condition changes for enhancing the voltage contrast such as the increase of the current amount and the increase of the voltage gradient on the sample are performed. Thereafter, the beam alignment and the automatic adjustment of the contrast and brightness are performed again. Through the process described above, the charging voltage on the surface is reduced to be lower than the allowable amount Va, and the conditions are optimized by changing the irradiation condition of the beam so as to set the charging voltage capable of providing the good image quality.

After the optimization of irradiation condition of the electron beam, the focal point/astigmatic adjustment and the height adjustment are completed, the alignment on the wafer 18 is started, Since the method used in the usual review SEM (Scanning Electron Microscope) or the inspection SEM can be used for this alignment, the description thereof will be omitted here.

After the completion of the alignment, the evaluation is started. The stage is moved in accordance with the imaging pitch set initially on the chip to be evaluated and images at each position are obtained. It is finished when a predetermined number of images are obtained. When forming the images, the frames are added in accordance with the number of images to be added and the parameters of weighting for the addition set initially. The images are stored in a storage system such as a personal computer connected to the system.

Next, the data for calibrating the obtained image signals is obtained. While all conditions such as the parameters of the irradiation condition and image addition are kept the same conditions as those when the images are obtained at the plugs to be evaluated, the stage is moved so that the center of the electron optics is moved to the edge portion of the wafer holder, and the electron beam is irradiated to the sample piece of the Si bare wafer attached to the holder edge. Then, the image is obtained and the signal value is calculated in the same manner as that of the plug portion. The signal obtained from the Si bare wafer is the secondary electron signal from the sample scarcely charged, that is, the sample with sufficiently low resistance, and is the signal corresponding to the maximum value of the secondary electron signal in the graph of FIG. 9 showing the relation between the secondary electron signal and the leakage current. The signal from the Si bare wafer is denoted by Smax. Further, as the sample with sufficiently high resistance, the signal from the oxide film with almost no electrical conduction to the substrate of the wafer is obtained and is stored as the signal Smin corresponding to the minimum value of the secondary electron signal in FIG. 9. It is also possible to obtain the image of the oxide film together with the image of the plug portion. Since Smax and Smin are obtained as described above, the value of the secondary electron signal S obtained in the plug portion to be evaluated can be calibrated in accordance with the above-described expression 1. In this manner, the translation from the secondary electron signal S to the secondary electron signal Sr and translation from the calibrated signal amount Sr to the leakage current can be performed.

Next, from a large number of images obtained from the plug portion to be evaluated and then stored, the secondary electron image signal of each plug is extracted, and the image signal of each plug portion is calculated. This image signal is calculated by, for example, averaging the signals of the pixels in the plugs. By repeating this process, the image signals of, for example, more than one hundred thousand plugs are extracted and calculated from a series of images, and the probability distribution of the images is displayed. The horizontal axis thereof at this time is the relative value of the secondary element signal, that is, the gray level of the images before calibration. However, the calibration of the secondary electron signal is performed in accordance with the expression 1. Then, the calibrated secondary electron signal is translated into the leakage current based on the relation between the leakage current and the secondary electron signal amount shown in FIG. 9.

Further, since the relation between the charging voltage Vw on the plug surface and the voltage Vpn applied to the junction portion is calculated or estimated as shown in FIG. 11, the voltage Vpn applied to the junction in the evaluation can be obtained. After calculating the difference between the voltage Vpn and the voltage condition V1 applied to the junction in the actual operation, the horizontal axis of the probability distribution is translated into the leakage current value in the actual operation by using the relation between the leakage current and Vpn shown in FIG. 10. Also, based on the estimation value of the temperature in the evaluation, it is translated into the leakage current value under the temperature condition of the actual operation. By doing so, the leakage current distribution generated when the device is actually operated as a product is accurately calculated. Further, the data retention time tREF is calculated by using various conditions of the device such as the data line capacity and SN capacity of the device and the margin of a sense amplifier.

As a result, it is possible to obtain the probability distribution to the data retention time tREF. Consequently, the main profile and the tail profile of the data retention time of the DRAM can be easily obtained. It is also possible to increase the accuracy of the evaluation by increasing the number of obtained images and the plugs so as to detect the low-frequency abnormal bits.

### Second Embodiment

Next, as the second embodiment, the manufacturing method of a semiconductor device will be described, in which the evaluation method shown in the first embodiment is applied to the manufacturing process of a semiconductor device to give the feedback to the semiconductor manufacturing conditions in an early stage. By applying the evaluation method in the course of the manufacturing process, it becomes possible to know the leakage current distribution of a DRAM, the leakage current of the normal bits which form the main profile and that of the abnormal bits which form the tail profile, and the number and ratio of the abnormal bits in an early stage. Consequently, the process conditions capable of reducing the leakage current and the number and ratio of the abnormal bits can be determined in the step of forming a junction in a shorter time than that of the conventional technology.

In the development of the DRAM, the evaluation of the reverse bias current in the pn junction portion in an early stage is quite effective for reducing the development period. As the method for determining the optimum conditions of the impurity profile of the pn junction in the current development of the process, for example, after the wafers processed under the various process conditions in which the annealing conditions are changed with using the time and the temperature as parameters are completed, the wafers are evaluated by the electric test. Then, the process with the best data retention property, that is, the lowest reverse bias current is selected. However, since the method described above requires two or three months to evaluate the reverse bias current and give the feedback of the process, it has been an obstacle for shortening the development period.

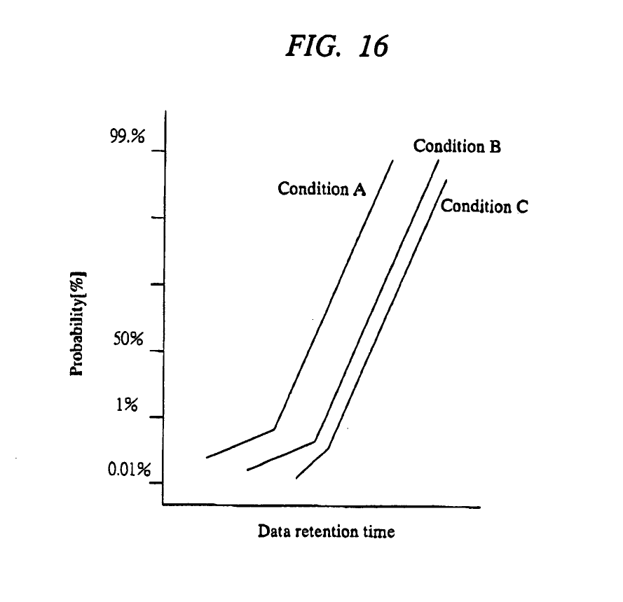

By measuring the leakage property of the pn junction in the course of the manufacturing process of a semiconductor device by using the inspection method of the present invention, the period required to give the feedback can be shortened, which can contribute to the shortening of the development period. The example in which the annealing condition is determined in the step of forming the pn junction during the development period of a DRAM will be described. For the comparison of the case where the annealing conditions are T1 [° C.] and t1 [second] (condition A), case where the annealing conditions are T2 [° C.] and t2 [second] (condition B) and the case where the annealing conditions are T3 [° C.] and t3 [second] (condition C), the junction is formed and the annealing process is performed under the respective conditions. Then, the wafers are taken out from each process line, and the evaluation method of the present invention is executed under the same irradiation condition. FIG. 16 shows the obtained result.

According to the results, the data retention time of the main profile tends to increase in the order of the conditions A, B and C. Also, when paying attention to the tail profile, the probability is high at the turning point from the main profile to the tail profile in the condition A, and the ratio of the abnormal bits is high. On the other hand, the probability at the turning point to the tail profile becomes lower in the order of conditions B and C, and the ratio of the abnormal bits is also reduced. In addition, the slope of the tail profile is larger in the condition C than those of the conditions A and B, and the minimum value of the data retention time in condition C is longer than those of the conditions A and B. In view of these facts, the wafer annealed under the condition C has the longest data retention time, fewest abnormal bits and the longest data retention time of the abnormal bits. Therefore, the condition C is selected as the optimum process condition.

As described above, the process condition can be evaluated just after forming the pn junction. By introducing the inspection method according to the present invention, the period for determining the optimum process conditions which has been more than 6 months in the conventional technology can be shortened.

### Third Embodiment

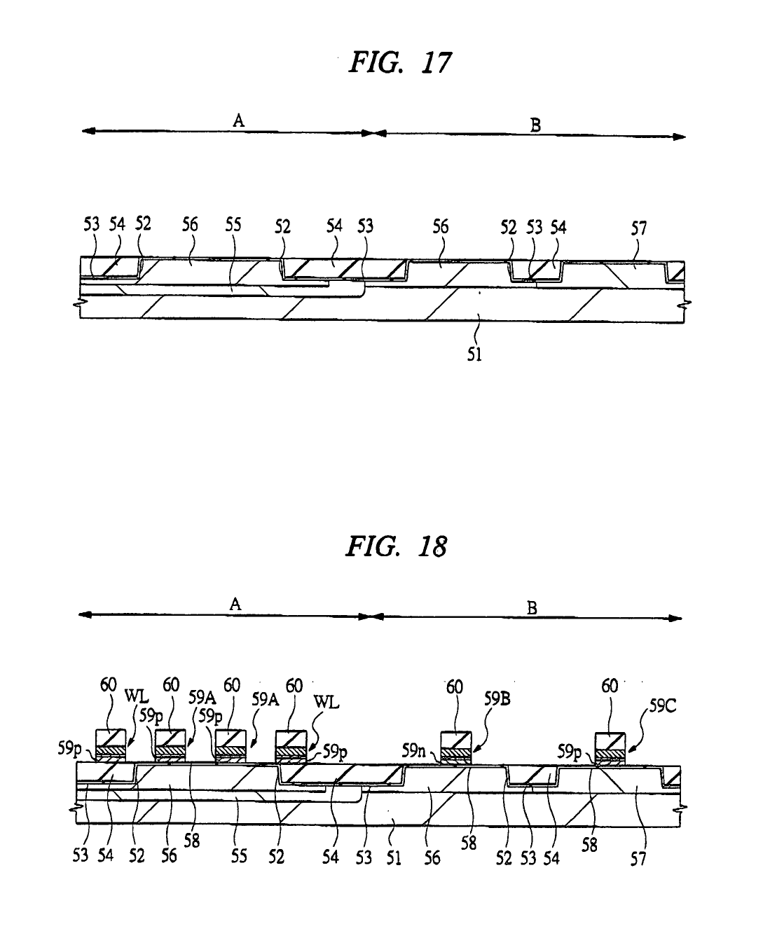

The case where the present invention is applied to the wafer in the manufacturing line processed through the steps shown in FIG. 17 to FIG. 20 in the manufacturing process of a stack-type DRAM to give the feedback to the adjustment conditions of the processing apparatus will be described below.

As shown in FIG. 17, a p type substrate 51 with a specific resistance of about 10 Ωcm is prepared, and shallow trenches 52 are formed in the main surface of the substrate 51. Thereafter, a silicon oxide film 53 is formed by the thermal oxidation of the substrate 51. Then, a silicon oxide film is deposited and is polished by the CMP (Chemical Mechanical Polishing) to leave the silicon oxide film only in the shallow trenches 52, thereby forming the isolation areas 54. Next, a n type impurity, for example, phosphorus (P) is ion-implanted into the area (A area: memory array) of the substrate 51 on which the memory cell is to be formed, thereby forming the deep n type well 55. Also, a p type impurity, for example, boron (B) is ion-implanted into the memory array and a part of the peripheral circuit (B area) (area in which the n channel MISFET is to be formed), thereby forming the p type well 56. In addition, a n type impurity, for example, phosphorus is ion-implanted into the other part of the peripheral circuit (area on which the p channel MISFET is to be formed), thereby forming the n type well 57. Also, after the ion implantation, an impurity for adjusting the threshold voltage of the MISFET, for example, boron fluoride (BF₂) is ion-implanted into the p type well 56 and the n type well 57.

Next, as shown in FIG. 18, a clean gate insulating film 58 made of silicon oxide with a thickness of about 6 to 7 nm is formed on each surface of the p type well 56 and the n type well 57 by the wet oxidation at about 850° C. for the substrate 51. Then, the gate electrodes 59A, 59B and 59C are formed on the gate insulating film 58. The gate electrode 59A constitutes a part of the MISFET for selecting memory cell and functions as a word line WL in the area other than the active area. The gate electrodes 59B and 59C constitute a part of each of the n channel MISFET and the p channel MISFIT of the peripheral circuit. For example, the gate electrode 59A (word line WL) and the gate electrodes 59B and 59C are formed in the following manner.

First, a layer made of a material with a bandgap smaller than that of silicon (Si), for example, a silicon germanium layer with a thickness of about 50 to 100 nm is epitaxially grown on the whole surface by the MBE (Molecular Beam Epitaxy) method or the CVD method. Thereafter, a p type impurity such as boron is ion-implanted into the area of the memory array and the peripheral circuit. on which the p channel MISFET is to be formed, thereby making the conductivity type of the silicon germanium layer p type and forming a p⁺ type silicon germanium layer (hereinafter, referred to as p⁺ poly SiGe film) 59p. Furthermore, a n type impurity, for example, phosphorus is ion-implanted into an area of the peripheral circuit on which the n channel MISFET is to be formed, thereby forming a n⁺ type silicon germanium layer (hereinafter, referred to as n⁺ poly SiGe film) 59n. Germanium (Ge) or silicon germanium carbon (SiGeC) may be deposited instead of silicon germanium.

Subsequently, a barrier layer made of tungsten nitride and a refractory metal film made of tungsten are sequentially deposited by the sputtering method on the p⁺ poly SiGe film 59p and the n⁺ poly SiGe film 59n, and a silicon nitride film 60 is deposited thereon by the CVD. Thereafter, these films are patterned with using a resist film as a mask. By doing so, the gate electrode 59A (word line WL) formed by laminating the p⁺ poly SiGe film 59p, a barrier layer and the refractory metal film in this order from below is formed in the memory array, the gate electrode 59B formed by laminating the n⁺ poly SiGe film 59n, the barrier layer and the refractory metal film in this order from below is formed in the area of the peripheral circuit in which the n channel MISFET is to be formed, and the gate electrode 59C formed by laminating the p⁺ poly SiGe film 59p, the barrier layer and the refractory metal film in this order from below is formed in the area of the peripheral circuit in which the p channel MISFET is to be formed. Note that the thickness of the barrier layer is, for example, about 10 nm, the thickness of the refractory metal film is, for example, about 100 nm, and the thickness of the silicon nitride film 60 is, for example, about 150 nm.

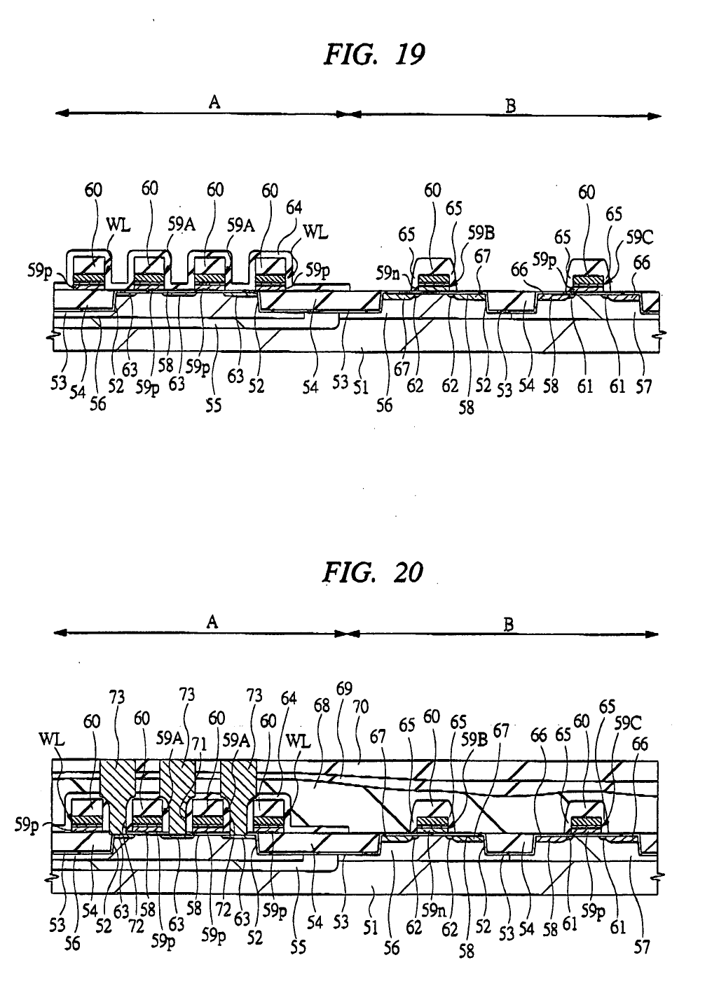

Next, as shown in FIG. 19, a p type impurity such as boron is ion-implanted into the n type well 57 of the peripheral circuit, thereby forming p⁻ type semiconductor areas 61 in the n type well 57 on both sides of the gate electrode 59C. Also, a n type impurity such as phosphorus is ion-implanted into the p type well 56 of the peripheral circuit, thereby forming n⁻ type semiconductor areas 62 in the p type well 56 on both sides of the gate electrode 59B. Furthermore, a n type impurity such as phosphorus is ion-implanted into the p type well 56 of the memory array, thereby forming n type semiconductor areas 63 in the p type well 56 on both sides of the gate electrode 59A. In this manner, the MISFET for selecting memory cell is approximately completed in the memory array.

Next, after a silicon nitride film 64 with a thickness of about 50 nm is deposited on the substrate 51 by the plasma CVD method, the silicon nitride film 64 of the memory array is covered with a resist film, and the silicon nitride film 64 of the peripheral circuit is anisotropically etched. By doing so, sidewall spacers 65 are formed on the sidewalls of the gate electrodes 59B and 59C. Next, after removing the resist film described above, a p type impurity, for example, boron is ion-implanted into the n type well 57 of the peripheral circuit to form the pa type semiconductor areas 66 (source, drain) of the p channel MISFET, and then, a n type impurity, for example, arsenic (As) is ion-implanted into the p type well 56 of the peripheral circuit to form the n⁺ type semiconductor areas 67 (source, drain) of the n channel MISFET. In this manner, the p channel MISFET and the n channel MISFET are approximately completed in the peripheral circuit.

Next, as shown in FIG. 20, after spin-coating a SOG (Spin On Glass) film 68 with a thickness of about 300 nm on the substrate 51, the SOG film 68 is sintered by the thermal treatment of the substrate 51 at 800° C. for 60 seconds.

Next, after depositing a silicon oxide film 69 with a thickness of about 600 nm on the SOG film 68, the silicon oxide film 69 is polished by the CMP method to planarize the surface thereof. The silicon oxide film 69 is deposited by the plasma CVD method using TEOS (Tetra Ethyl Ortho Silicate: Si(OC₂H₅)₄) and ozone (O₃) as source gas.

Next, a silicon oxide film 70 with a thickness of about 100 nm is deposited on the silicon oxide film 69. The silicon oxide film 70 is deposited in order to repair the microscopic cracks on the surface of the silicon oxide film 69 formed by the CMP method. The silicon oxide film 70 is deposited by, for example, the plasma CVD method using TEOS and ozone as the source gas. The PSG (Phospho Silicate Glass) film can be deposited on the silicon oxide film 69 instead of the silicon oxide film 70.

Next, a resist film is formed on the silicon oxide film 70, and then, the silicon oxide films 70 and 69 and the SOG film 68 on the n type semiconductor areas 63 (source, drain) of the MISFET for selecting memory cell are removed by the dry etching with using this resist film as a mask. Subsequently, the silicon nitride film 64 and the gate insulating film 58 on the n type semiconductor areas 63 (source, drain) of the MISFET for selecting memory cell are removed by the dry etching using the above-described resist film as a mask. By doing so, the contact hole 71 is formed on one of the n type semiconductor areas 63 (source, drain) and the contact hole 72 is formed on the other thereof.

Next, after removing the resist film, plugs 73 are formed in the contact holes 71 and 72. The plugs 73 are formed in the following manner. That is, after depositing a polysilicon film introduced with a n type impurity (for example, phosphorus) on the silicon oxide film 70 by the CVD method, the polysilicon film is polished by the CMP method so as to leave it in the contact holes 71 and 72.

As described in the conceptual diagram of FIG. 6, the electron beam is irradiated to the wafer on which the embedded surfaces of the plugs 73 are exposed, thereby evaluating the leakage property of the pn junction. By using the evaluation procedure of the present invention described in the first embodiment, the leakage property distribution of the pn junction is evaluated at a plurality of positions on the wafer under the same evaluation condition, and the within-wafer variation of the property distribution is obtained. By doing so, the positional dependency of the performance of the processing apparatus operated under the same condition becomes apparent, and thus, it becomes possible to give the feedback to the adjustment conditions of the processing apparatus.

Also, by regularly taking out the wafer manufactured under the same condition to evaluate the leakage property distribution thereof in accordance with the evaluation method of the present invention, the change over time of the performance of the processing apparatus under the same condition can be obtained. Therefore, the process management in which the evaluation results of the leakage property can be kept constant can be realized by changing the processing conditions. More specifically, the inline monitoring in which the performance of the wafer fabrication is evaluated in the manufacturing line in real time to give the feedback to the processing conditions (for example, temperature condition of annealing, annealing time, ion implantation condition, etching process condition, various film-forming condition, and others) can be realized. Consequently, the fluctuation in processes, which has been obtained by the electric test performed after the completion of the wafer in the conventional technology, can be corrected in situ, and the drastic enhancement of the yield can be achieved.

In the foregoing, the representative system structure and evaluation method according to the present invention have been described. However, it is needless to say that they can be realized even by the partially different method and structure without departing from the scope of the present invention. In the case described above, the data obtained from a wafer is calibrated and the absolute values thereof are obtained. Other than this method, however, the following method is also available. That is, after the reference wafer whose evaluation result is known is prepared in advance, the same evaluation is performed also for the prepared reference wafer when performing the evaluation of the wafer to be evaluated, and the relative comparison therebetween is performed to obtain the result. Also, in the embodiment above, the case where the number of detectors of the secondary electrons is one has been described. However, it is also possible to provide a plurality of detectors. More specifically, it is possible to separately provide the detector used when the energy filter is ON, that is, used to measure the voltage and the detector used when the filter is OFF, that is, used to evaluate the leakage property. It is also possible to provide a deflector which deflects only the secondary electrons at a certain position on the optical path of the secondary electrons in order to lead the secondary electrons to the detector. With respect to the extraction method of the image signals of the plugs, the case where all of the signals of each plug are averaged and extracted has been described in this case. However, it is not always necessary to use all of the internal signals. That is, the method in which only the necessary data is emphasized and extracted by ignoring the signals near the center of each plug or adopting the signals of the outline part of each plug is also available. In addition, the numerical values shown in the above-described embodiments are mere examples.

Furthermore, in the calibration method in the above-described embodiments, the reference sample is attached to the edge of the holder so as to obtain the reference signal for calibrating the evaluation result. Of course, it is not limited to this method. If there is the part on which the Si substrate is exposed on the wafer to be evaluated, it is possible to use the part as the reference sample. Also, the method in which the plug formed on the device isolation insulating film in the wafer and the plug formed on the N diffusion layer on the n well are provided in advance and the signals obtained from them are used for the calibration as S_min and S_max in the first embodiment is performed. As a result, although it has been necessary to change the adjustment conditions of the focal point and the astigmatic adjustment by comparing with the electron optics conditions in the evaluation of the plugs when the samples are provided on the holder edge portion and the wafer edge portion, if there is the reference samples fabricated within the wafer, the calibration under the same conditions without changing any electron optics conditions from those of the evaluation-can be executed, and thus, the accuracy of the calibration is further improved. Furthermore, in the embodiment described above, the calibration signals are obtained from the part having complete electrical conduction to the holder and from the part having no electrical conduction thereto. However, the parts are not limited to them. If the signals with different brightness can be stably obtained from the two types of samples, the data calibration can be executed. Therefore, it is also possible to use the calibration samples made of different two metals of different elements attached to the holder or fabricated within the wafer.

In addition, the DRAM is used as an example in the above-described embodiments. However, the present invention is not limited to this. For example, the present invention can be applied to all semiconductor devices having a pn junction such as the flash memory and the CMOS. In addition, other than the electron beam, a charged particle beam such as the FTB (Focused Ion Beam) is also available in the present invention.

The present invention can be applied to the manufacture of a semiconductor device.

1. An evaluation method of a semiconductor device, comprising the steps of:
irradiating a primary charged particle beam to a surface of a wafer in the course of a manufacturing process of a semiconductor device having a pn junction;
detecting electron Signals secondarily generated from a conductive material connected to the pn junction formed on said wafer by the irradiation of said primary charged particle beam;
imaging said detected electron signals to measure the charging voltage of said conductive material;
determining irradiation conditions of said primary charged particle beam which can set the charging voltage of said conductive material with in a desired range;
obtaining said image under said irradiation conditions of the primary charged particle beam and extracting voltage contrast signals; and
obtaining electrical properties of the pn junction which constitutes said semiconductor device based on said voltage contrast signals.

2. An evaluation method of a semiconductor device, comprising the steps of:
irradiating a primary charged particle beam to a surface of a wafer in the course of a manufacturing process of a semiconductor device in which an electrode lead-out plug and a pn junction formed below said plug are formed;
detecting electron signals secondarily generated from the surface of said wafer by the irradiation of said primary charged particle beam;
imaging said detected electron signals to measure the charging voltage of the surface of said plug;
determining whether or not said measured charging voltage is within a desired range;
changing irradiation conditions of said primary charged particle beam to change said charging voltage;
obtaining said image under the irradiation conditions of said primary charged particle beam in which said charging voltage is within the desired range;
extracting voltage contrast signals from the information of said image; and obtaining electrical properties of the pn junction which constitutes said semiconductor device based on said voltage contrast signals.

3. The evaluation method of a semiconductor device according to claim 1,
wherein the primary charged particle beam is irradiated several times at predetermined intervals to the wafer surface in the course of the manufacturing process of a semiconductor device.

4. The evaluation method of a semiconductor device according to claim 1,
wherein said primary charged particle beam is electron beam or FIB (Focused Ion Beam).

5. The evaluation method of a semiconductor device according to claim 2,
wherein the primary charged particle beam is irradiated several times at predetermined intervals to the wafer surface in the course of the manufacturing process of a semiconductor device.

6. The evaluation method of a semiconductor device according to claim 2,
wherein said primary charged particle beam is electron beam or FIB (Focused Ion Beam).

7. The evaluation method of a semiconductor device according to claim 1,
wherein said conductive material connected to the pn junction is an electrode lead-out plug having the pn junction below it.

8. The evaluation method of a semiconductor device according to claim 1,
wherein said desired range of the charging voltage on the surface of said conductive material is the range of the charging voltage, in which the electrical properties of the pn junction which constitutes said semiconductor device are almost the same electrical properties of said semiconductor device in an actual operation, or is the range in which the electrical property has the linearity over said charging voltage.

9. The evaluation method a semiconductor device according to claim 2,
wherein said step of obtaining an image includes the step of irradiating said primary charged particle beam also to two types of calibration samples in addition to said electrode lead-out plugs of said wafer, thereby obtaining the images thereof and calibrating numerical values of the images signals of said electrode lead-out plugs.

10. The evaluation method of a semiconductor device according to claim 2,
wherein said step of obtaining an image includes the step of irradiating said primary charged particle beam also to a position having electrical conduction to a substrate of said wafer and a position having no electrical conduction to the substrate in addition to said electrode lead-out plugs of said wafer, thereby obtaining the images thereof and calibrating numerical values of the image signals of said electrode lead-out plugs.

11. The evaluation method of a semiconductor device according to claim 2,
wherein said method further includes the step of irradiating said primary charged particle beam to the semiconductor device having a portion in which plugs have the ohmic conduction to a semiconductor substrate and a portion in which plugs are formed in the position having no electrical conduction to the semiconductor substrate, in addition to said electrode lead-out plugs of said wafer, thereby obtaining the images thereof and calibrating numerical values of the image signals of said electrode lead-out plugs to be evaluated.

12. (canceled)

13. The evaluation method a semiconductor device according to claim 1,
wherein said method further comprises the step of: obtaining leakage current or the like of a pn junction, which constitutes said semiconductor device, based on said voltage contrast signal and said charging voltage.

14. The evaluation method a semiconductor device according to claim 2,
wherein said method further comprises the step of: obtaining leakage current or the like of a pn junction, which constitutes said semiconductor device, based on said voltage contrast signal and said charging voltage.

15. The evaluation method a semiconductor device according to claim 2,
wherein, in said step of extracting said voltage contrast signal, said voltage contrast signal is extracted from said plurality of electrode lead-out plugs to calculate a histogram of said extraction result.

16. The evaluation method of a semiconductor device according to claim 2,
wherein said primary charged particle beam is irradiated to said semiconductor device to form a reverse bias voltage state in said pn junction formed below said plug.

17. The evaluation method of a semiconductor device according to claim 2,
wherein said step of imaging said electron signals is the step of performing addition, in which a desired weighting is given to electron signals generated by the predetermined irradiations among the electron signals generated by irradiating said primary charged particle beam to said wafer surface several times.

18-20. (canceled)
